(19) United States
(12) Patent Application Publication
(10) Pub. No.: US 2010/0018757 A1
(43) Pub. Date: Jan. 28, 2010

(54) Printed circuit board (PCB) with slot for pass through terminal (PTT), method of drilling a slot in a printed circuit board and printed circuit board assembly with slot and pass through terminal

(76) Inventor: Juan I. Banzo, Cd Juarez (MX)

Correspondence Address: Delphi Technologies, Inc., M/C 480-410-202, PO BOX 5052, Troy, MI, 48007, US

(21) Appl. No.: 12/220,224

(22) Filed: Jul. 23, 2008

(51) Int. Cl. H05K 1/02; H05K 3/00

(52) U.S. Cl. 174/255; 29/829

(57) ABSTRACT

A printed circuit board assembly comprises a printed circuit board and a pass through terminal. The printed circuit board has a wavy slot extending through the printed circuit board that is clad with a conductive material. The wavy slot has part circular ends and a plurality of cusps along each side of the wavy slot that are formed by a plurality of successive drill cuts through a substrate of the printed circuit board. The pass through connector has a rectangular mounting portion that is disposed in the wavy slot with an interference fit so as to deform the part circular ends of the wavy slot at four locations and the cusps along each side of the wavy slot.

### BACKGROUND OF THE INVENTION

This invention relates to a printed circuit board having a drilled slot for a pass through terminal, a method for drilling the slot in the printed circuit board and an assembly comprising the printed circuit board having a drilled slot and a pass through terminal extending through the drilled slot.

Pass through terminals are commonly used with printed circuit boards that are prepared with apertures into which the terminals are inserted. The apertures through which the terminals pass may take various shapes. Slots and round holes are the most common shapes. Slots and round holes may simply be punched through individual printed circuit board substrates. However it is common practice to drill slots and round holes apertures through a stack of printed circuit board substrates. Round holes are drilled easily. However in the case of slots, it has been the practice to drill through the stack of substrates several times in order to approximate a slot with substantially parallel edges. For instance in a known method, the slots are drilled more than an average of eleven times per millimeter of slot length with the drill center being moved less than a tenth of a millimeter in each successive drilling operation. This known method is very expensive because of the large number of drill passes. Moreover, the electrical and mechanical connection between the pass through terminal and the printed circuit board relies solely on an interference fit of the four corners of a substantially rectangular mounting portion of the pass through terminal with the rounded corners of the drilled slot.

This mechanical and electrical connection between the pass through connector and the printed circuit board is generally enhanced with a solder connection in a secondary operation.

### SUMMARY OF THE INVENTION

This invention involves a printed circuit board having a drilled slot that is drilled with substantially fewer passes than existing drilled slots. Moreover, the drilled slot provides an improved electrical and mechanical connection between the pass through terminal and the printed circuit board.

### BRIEF DESCRIPTION OF THE DRAWINGS

FIG. 1 is a perspective fragmentary view of a printed circuit board assembly illustrating a preferred embodiment of the invention;

FIG. 2 is a schematic diagram showing a step in the process of making the printed circuit board of the printed circuit board assembly shown in FIG. 1;

FIG. 3 is a top view of the printed circuit board substrate of the printed circuit board assembly shown in FIG. 1;

FIG. 4 is a top view of the printed circuit board of the printed circuit board assembly shown in FIG. 1;

FIG. 5 is a top view of the printed circuit board assembly shown in FIG. 1; and

FIG. 6 is a partially sectioned perspective view of the printed circuit board assembly shown in FIG. 1.

### DETAILED DESCRIPTION OF PREFERRED EMBODIMENTS

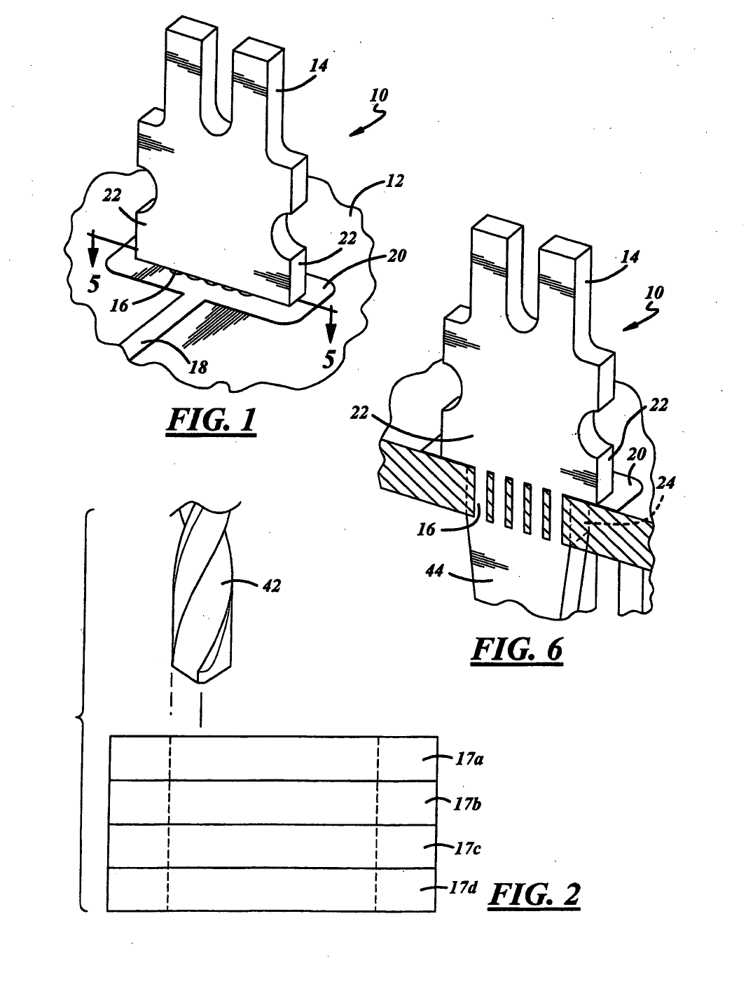

Referring now to FIG. 1, a printed circuit board assembly 10 comprises a printed circuit board 12 and a pass through terminal 14 that projects through a slot 16 of the printed circuit board 12.

The printed circuit board 12 comprises an electrically insulated substrate 17 and conductor strip or strips 18 of thin copper (one shown) that are arranged to provide a desired circuit. Slot 16 is surrounded by a contact pad 20 which is engaged by wings 22 of the pass through terminal 14 to establish an electrical connection between the pass through terminal 14 and the conductor strip 18 that is contiguous the contact pad 20.

Terminal 14 has a mounting portion 24 of rectangular cross section beneath the wings 22 that is disposed in the slot 16 with an interference fit at each end and at several locations along the longer side of the rectangular mounting portion 24. This interference fit results from a “wavy” shape of the slot 16 which includes part-circular ends 26 and a plurality of cusps 28 that are spaced from each other along each of the longer sides of the slot 16 with the cusps 28 being arranged in pairs on opposite sides of the drilled slot.

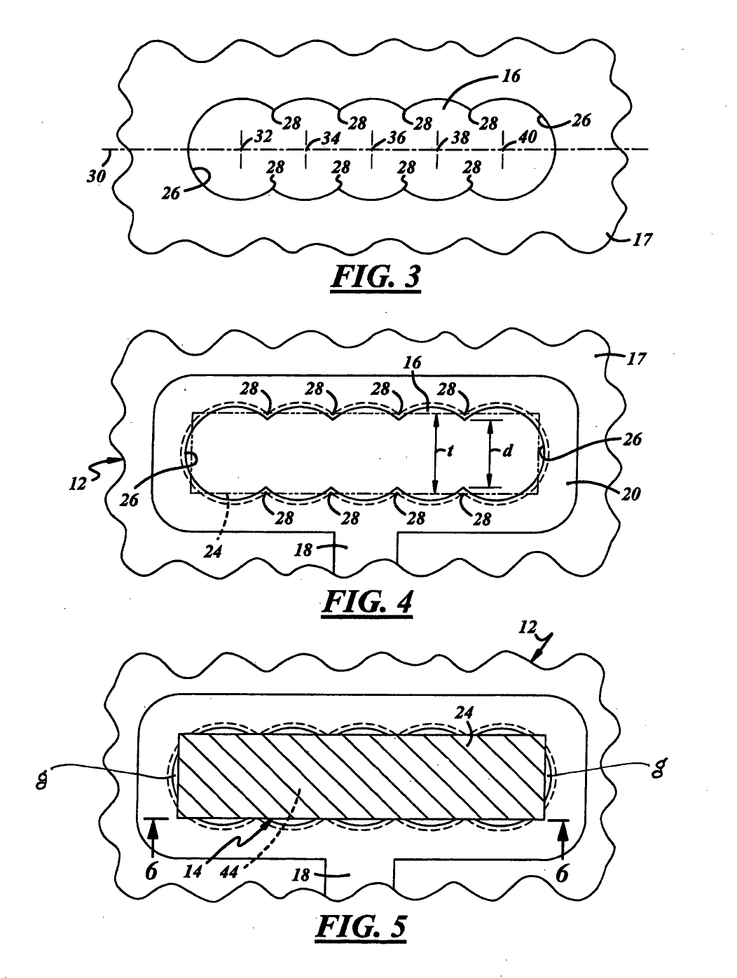

The part circular ends 26 and cusps 28 are produced by a drilling operation in which several successive drill cuts are made through the substrate 17. For instance to produce the wavy slot 16 shown in FIG. 3, a series of round drill cuts are made successively at spaced centers along a center line 30. More specifically, a first round drill cut is made at a center 32 on centerline 30, then a second round drill cut at a center 34, then a third round drill cut at a center 36, then a fourth round drill cut at a center 38 and then a final drill cut at a center 40. This produces the “wavy” slot 16 with the part-circular ends 26 and the plurality of spaced cusps 28. While the successive drilling of the “wavy” slot 16 has been described in connection with a single substrate 17, it should be understood that a stack of several substrates, such as the representative stack of substrates 17a, 17b, 17c and 17d illustrated in FIG. 2 which are positioned beneath a drill 42 for forming “wavy” slots extending through the stack of substrates by successive cuts of the drill 42.

After the “wavy” slot 16 is drilled through the substrate 17 as shown in FIG. 3, the substrate 17 is selectively plated with a conductive material, usually copper, with any well known technique. As shown in FIG. 4, the slot 16 is plated with a thin layer of conductive material, while the top and/or bottom surface of the substrate 17 are plated around the slot 17 with a thin layer of conductive material to form the 20 pad and the circuit trace 18 to form the circuit board 12.

The “wavy” slot 16 in the plated circuit board 12 has twelve (12) interference areas for retaining the rectangular mounting portion 24 of the pass through terminal 14. This is illustrated in FIG. 4 by showing the rectangular mounting portion 24 of the pass through terminal 14 is phantom. In addition to the four conventional interference areas 46 at the four corners of the rectangular mounting portion 24, there are eight interference areas along the sides of the rectangular mounting portion 24 formed by the eight cusps 28 with the cusps 28 on one side being spaced from the cusps 28 on the opposite side by a distance “d” that is less the nominal thickness “t” of the rectangular mounting portion 24 of the pass through terminal 14. The distances “d” and “t” are typically about 0.82 millimeters and .99 millimeters respectively while the gaps at each ends of the mounting portion 24 is typically about 0.07 millimeter.

After the printed circuit board is plated, the tail 44 of the pass through terminal 14 is then inserted into the conductive material clad “wavy” slot 16 until the rectangular mounting portion 24 of the pass through terminal 14 is disposed in the clad “wavy” slot 16 with an interference fit as shown in FIGS. 1, 5 and 6. The rectangular mounting portion 24 makes an excellent electrical and mechanical connection with the printed circuit board 12 because the four corners of the rectangular mounting portion 24 interfere with and deform the part-circular ends of the “wavy” slot at four locations while the sides of the rectangular mounting portion 24 also interfere with and deform four cusps 28 on each side.

The pass through terminal 14 preferably includes wings 22 to engage the top of the printed circuit board 12 to show that the mounting portion 24 is fully inserted into the “wavy” slot 16 as best shown in FIG. 6.

In some instances, for example, in low current applications, the interference fit of the pass through terminal 14 in the conductive material clad “wavy” slot 16 may be sufficient. However, in other instances, after mounting to the printed circuit board 12, the pass through terminal 14 may be soldered in place with conventional techniques to enhance the electrical and mechanical connection of the pass through terminal 14 to the printed circuit board 12. In this regard it should be noted that the “wavy” slot 16 reduces the gaps between the rectangular mounting portion 24 and the clad “wavy” slot 16 which in turn reduces the amount of solder needed to solder the pass through terminal 14 to the printed circuit board 12.

When forming the “wavy” slot 16, the diameter of the drill 42 is greater than the nominal width of the rectangular mounting portion 24 of the pass through terminal 14 so as to produce the desired interference fit and reduced gaps between the rectangular mounting portion and the clad “wavy” slot 16.

The number of drill cuts through the printed circuit board 12 related to the nominal length of the rectangular mounting portion 24 of the pass through terminal 14 is reduced substantially.

The following chart is a comparison of the number of drill hits in a known method and in my method for various slot lengths

| | Known Drill | | | |
|---|---|---|---|---|
| Slot Length | Hits | Per MM | My Drill Hits | Per MM |
| 3.6 mm | 41 | 11.389 | 9 | 2.500 |
| 3.53 mm | 40 | 11.331 | 9 | 2.550 |
| 4.06 mm | 46 | 11.048 | 9 | 2.217 |
| 6.73 mm | 76 | 11.293 | 17 | 2.526 |
| Average | | 11.274 | | 2.448 |

As shown by the above chart, the number of drill hits has been reduced in the range of 77.5% to 80% or an average of about 78% which is substantial.

The following chart is a comparison of the number of retention or interference points per side between current printed circuit board with conventional drilled slots and my printed circuit boards with drilled “wavy” slots.

| | Current Retention | | Wavy Slot | |
|---|---|---|---|---|
| | Points | | Retention Points | |
| | | Per Side Per | | Per Side Per |
| Slot Length | Per Side | MM | Per Side | MM |
| 3.6 mm | 2 | 0.56 | 10 | 2.78 |
| 3.53 mm | 2 | 0.57 | 10 | 2.83 |
| 4.06 mm | 2 | 0.49 | 10 | 2.67 |
| 6.73 mm | 2 | 0.30 | 18 | 2.67 |
| Average | | 0.48 | | 2.69 |

As shown by the chart, the number of retention points has been increased in the range of 396% to 790% or an average of about 460% which is substantial.

While the forms of the invention herein disclosed constitute presently preferred embodiments, many others are possible. It is not limited herein to mention all the possible equivalent forms or ramifications of the invention. It is understood that the terms used herein are merely descriptive rather than limiting and that various changes may be made without departing from the spirit or scope of the invention.

I claim:

1. A method of making a printed circuit board having a slot for a pass through terminal, the printed circuit board having a substrate wherein a wavy slot is drilled through the substrate in a plurality of successive drill cuts made at a plurality of respective centers spaced along an imaginary centerline of the wavy slot to produce a wavy slot having part-circular ends and a plurality of cusps along each side of the wavy slot.

2. The method of claim 1 wherein the plurality of cusps are arranged in pairs on opposite side of the wavy slot spaced apart by a distance “d” to provide interference areas for a pass through terminal which has a thickness “t” that is greater than the distance “d”.

3. The method of claim 1 wherein the slot has a predetermined millimeter length and the plurality of successive drill cuts is in the range of about 2.2 to 2.6 per millimeter of the predetermined millimeter length.

4. The method of claim 1 wherein the slot has a predetermined millimeter length and the plurality of successive drill cuts in about 2.5 per millimeter of the predetermined millimeter length.

5. The method of claim 1 wherein the wavy slot is clad with a conductive material.

6. A printed circuit board having a slot for a pass through terminal, the printed circuit board comprising:
a substrate having a wavy slot extending through the substrate,
the wavy slot having part circular ends and a plurality of cusps along each side of the wavy slot.

7. The printed circuit board of claim 6 wherein the plurality of cusps are arranged in pairs on opposite side of the wavy slot spaced apart by a distance “d” to provide interference areas for a pass through terminal which has a thickness “t” that is greater than the distance “d”.

8. The printed circuit board of claim 6 wherein the wavy slot is clad with a conductive material.

9. A printed circuit board assembly comprising:
a printed circuit board and a pass through terminal,
the printed circuit board having a substrate having a wavy slot extending through the substrate,
the wavy slot being clad with a conductive material and having part circular ends and a plurality of cusps along each side of the wavy slot,
the pass through terminal having a rectangular mounting portion that is disposed in the wavy slot with an interference fit,
the rectangular mounting portion having corners that interfere with and deform the part circular ends of the wavy slot at four locations and
the rectangular mounting portion having sides that interfere with and deform the cusps along each side of the wavy slot.

10. The printed circuit board assembly of claim 9 wherein the plurality of cusps are arranged in pairs on opposite side of the wavy slot that are spaced apart a distance “d” and the rectangular mounting portion of the pass through terminal having a thickness “t” that is greater than the distance “d”.
